(19) United States
(12) Patent Application Publication
(10) Pub. No.: US 2026/0367144 A1
(43) Pub. Date: Nov. 19, 2026

(54) PACKAGE TESTING DEVICE AND METHOD

(71) Applicant: STATS ChipPAC Management Pte. Ltd., Singapore (SG)

(72) Inventor: YoungIn CHOI, Chungcheongbuk-do (KR)

(21) Appl. No.: 19/675,532

(22) Filed: May 13, 2026

(30) Foreign Application Priority Data
May 14, 2025 (CN) 202510620297.X

(51) Int. Cl. G01R 31/28; G01R 1/04; H04N 23/57; H04N 23/90

(52) U.S. Cl. CPC G01R 31/2896; G01R 1/0433; G01R 31/2893; H04N 23/57; H04N 23/90

(57) ABSTRACT

A package testing method includes: a tray having a seat for receiving an electronic package with a set of backside conductive structures, and a set of openings formed at and passing through a bottom of the seat; a push head displaceable relative to the tray and configured to press the electronic package against the seat when the electronic package is received within the seat; wherein the push head has a cavity, and a frontside camera received in the cavity and configured to capture a frontside image of the electronic package; and a test socket board for performing an electrical test to the electronic package. The test socket board has a set of test pins operable to pass through the set of openings and be connected to the set of backside conductive structures to allow the test socket board to perform the electrical test to the electronic package.

### TECHNICAL FIELD

The present application generally relates to semiconductor technology, and more particularly, to a package testing device and a package testing method.

### BACKGROUND OF THE INVENTION

Electronic packages such as semiconductor packages need to be tested for electrical functionality and appearance defects before shipment, to ensure that they are in good quality. Accordingly, an electrical test (e.g., on functionality) and an appearance inspection check are performed separately for the electronic packages. However, the separate tests not only increase cost but also are low in efficiency.

Therefore, a need exists for an improved device and method for testing electronic packages.

### SUMMARY OF THE INVENTION

An objective of the present application is to provide a device and method for testing electronic packages with improved efficiency.

According to an aspect of the present application, a package testing device is provided. The package testing device comprises: a tray having a seat for receiving an electronic package with a set of backside conductive structures, and a set of openings formed at and passing through a bottom of the seat; wherein the set of openings are configured to expose the set of backside conductive structures when the electronic package is received in the seat; a push head displaceable relative to the tray and configured to press the electronic package against the seat when the electronic package is received within the seat; wherein the push head has a cavity, and a frontside camera received in the cavity and configured to capture a frontside image of the electronic package; and a test socket board for performing an electrical test to the electronic package, wherein the test socket board has a set of test pins which are operable to pass through the set of openings of the seat and be connected to the set of backside conductive structures of the electronic package to allow the test socket board to perform the electrical test to the electronic package.

According to another aspect of the present application, a package testing pipeline is provided. The package testing pipeline comprises: a tray loading site for placing a tray having a plurality of seats; wherein each of the plurality of seats is configured for receiving an electronic package with a set of backside conductive structures, and a set of openings formed at and passing through a bottom of the seat, and wherein the set of openings are configured to expose the set of backside conductive structures when the electronic package is received in the seat; a first testing site for placing a test socket board for performing an electrical test to the electronic packages received within the seats of the tray when the tray is transferred from the tray loading site onto the test socket board, and for placing a plurality of push heads displaceable relative to the test socket board and configured to press the electronic packages against the plurality of seats of the tray when the tray is on the test socket board; wherein each of the push heads has a cavity, and a frontside camera received in the cavity and configured to capture a frontside image of the electronic package; and wherein the test socket board has a plurality sets of test pins, and each set of test pins are operable to pass through the set of openings of a seat of the plurality of seats of the tray and be connected to the set of backside conductive structures of the electronic package within the seat to allow the test socket board to perform the electrical test to the electronic package; a second testing site having a backside camera, and an array of mirrors disposed above the backside camera and defining an inspection space and configured to reflect images of respective lateral surfaces of the electronic package in the inspection space to the backside camera to allow the backside camera to capture the images of the lateral surfaces of the electronic package and a backside image of the electronic package; and a transfer head configured to pick up the electronic package from one of the plurality of seats of the tray and transfer the electronic package to the second testing site.

According to a further aspect of the present application, a package testing method is provided. The package testing method comprises: loading an electronic package with a set of backside conductive structures in a seat of a tray which has a set of openings formed at and passing through a bottom of the seat, to expose the set of backside conductive structures of the electronic package through the set of openings; transferring the tray onto a test socket board having a set of test pins; pressing, via a push head having a cavity and a frontside camera received in the cavity, the electronic package against the seat to pass the set of test pins through the set of openings of the seat and connect the set of test pins to the set of backside conductive structures of the electronic package; capturing, via the frontside camera, a frontside image of the electronic package; and performing, via the test socket board, an electrical test to the electronic package.

According to a yet further aspect of the present application, a package testing method is provided. The package testing method comprises: placing a tray having a plurality of seats at a tray loading site, wherein each set of the plurality of seats has a set of openings formed at and passing through a bottom of the seat; loading an electronic package with a set of backside conductive structures within each of the plurality of seats to expose the set of backside conductive structures through the set of openings at the bottom of the seat; transferring the tray with the plurality of electronic packages from the tray loading site onto a test socket board having a plurality sets of test pins at a first testing site; pressing, via a plurality of push heads each having a cavity and a frontside camera received in the cavity, the electronic packages against the plurality of seats, respectively, to pass the plurality sets of test pins through the plurality sets of openings of the plurality of seats and connect the plurality sets of test pins to the plurality sets of backside conductive structures of the electronic packages; capturing, via the frontside cameras of the plurality of push heads, respective frontside images of the electronic packages; and performing, via the test socket board, an electrical test to the electronic packages.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIGS. 1A to 1E show a package testing method implemented by a pipeline according to an embodiment of the present application.

FIG. 2A shows a cross-sectional view of a seat placed on the test socket board at the first testing site shown in FIG. 1B.

FIG. 2B shows a cross-sectional view of an electronic package under appearance inspection at the second testing site shown in FIG. 1D.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As aforementioned, before shipment, electronic packages such as semiconductor packages need to be tested to check if they are in good quality. For example, an electrical test pipeline may be set up to perform an electrical test on electronic packages to check on whether they can function correctly. Also, another appearance inspection pipeline may be set up to perform appearance inspection on the electronic packages to identify those with undesired defects in appearance. These separated pipelines adversely affect the efficiency of testing these electronic packages.

To address the above issue, the inventors of the present application proposed a package testing device and pipeline which can implement both of the electrical test and the appearance inspection in a single process or pipeline. As such, the efficiency of testing and checking electronic packages is improved, and the cost can also be reduced significantly.

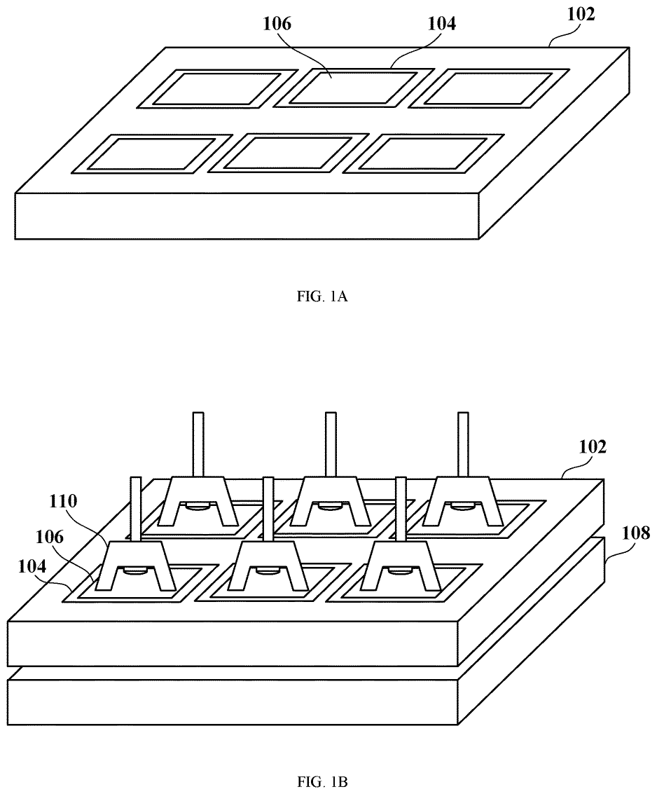

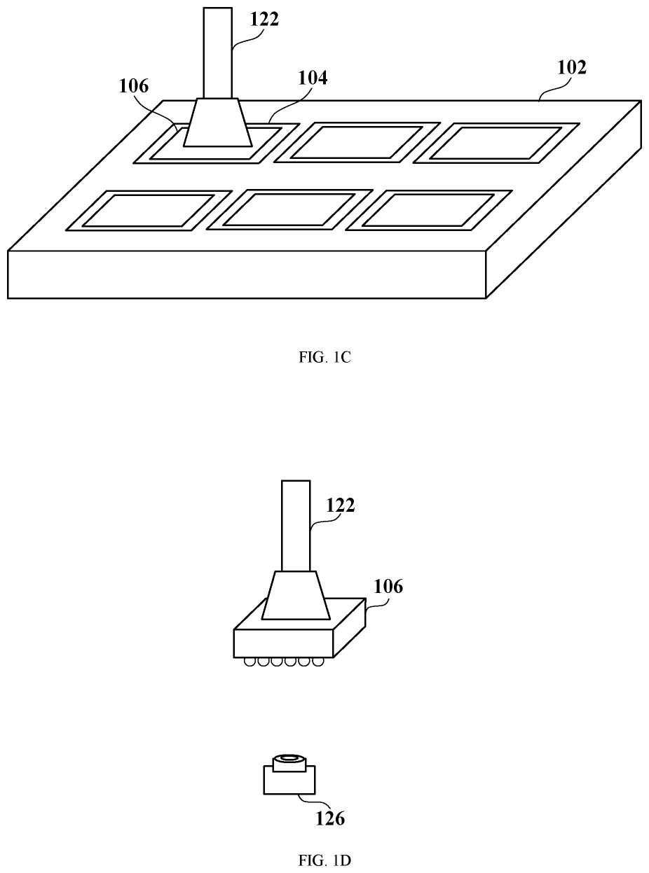

FIGS. 1A to 1E show a package testing method implemented by a pipeline according to an embodiment of the present application.

As shown in FIG. 1A, the testing process may start at a tray loading site. A tray 102 is placed at the tray loading site which can be in the form of a platform or a conveyer station, or any other similar carrier structures. In some embodiments, the tray 102 may have a plurality of seats 104, each of which is used to receive an electronic package 106 that is to be tested. The electronic package 106 may have a set of backside conductive structures (not shown) such as solder bumps or contact pads, through which circuitry within the electronic package 106 can be electrically connected to an external device. In particular, an electrical test can be performed on the electronic package 106 through the set of backside conductive structures, for example, input or drive signals may be applied to the electronic package 106 through some of the backside conductive structures, and output or feedback signals may be generated and outputted from the electronic package 106 through some of the backside conductive structures. It can be appreciated that in some examples other than the set of backside conductive structures through which the electrical testing can be implemented, the electronic package 106 may have other backside conductive structures which are not needed to be connected to a testing device for the electrical testing. The seats 104 of the tray 102 may have the same shape and structure, or be constructed differently. Also, although in the embodiment the tray 102 has a plurality of seats 104, in some alternative embodiments, the tray 102 may have only one seat 104.

Each seat 104 of the tray 102 may have a set of openings (not shown) formed at a bottom of the seat 104. The openings are through holes which pass through the bottom of the seat 104. The openings can be arranged in an array and layout the same as that of the set of backside conductive constructures of the electronic package 106 received within the seat 104. It can be appreciated that the openings may have a size similar to or great than that of the backside conductive structures. As such, when the electronic package 106 is received in the seat 104, the set of backside conductive structures can be exposed from the bottom of the seat 104 through the set of openings, and thus be ready for an electrical test.

Next, as shown in FIG. 1B, the tray 102 is transferred from the tray loading site to a first testing site where at least a portion of the electrical test and appearance inspection to the electronic packages 106 is performed. In particular, a test socket board 108 for performing the electrical test can be placed at the first testing site, e.g., placed on a platform or on a conveyor station. The tray 102 can be transferred to the first testing site by a conveyer or a robotic arm or similar means. After the transfer, the tray 102, with the electronic packages 106 received therein, is placed on the test socket board 108, and thus has the electronic packages 106 be connected to the test socket board 108. In order to enhance and maintain the connection between the electronic packages 106 and the test socket board 108, a plurality of push heads 110 are mounted above the test socket board 108 at the first testing site. The plurality of push heads 110 are displaceable relative to the test socket board 108, and used to press the electronic packages 106 against the plurality of seats 104 of the tray 102 when the tray 102 is placed on the test socket board 108. For example, the push heads 110 can move in a vertical direction between a press position and a release position. In the press position, the push heads 110 can be sufficiently close to the test socket board 108 to press the electronic packages 106 against the tray 102 or particularly the seats 104. In the release position, the push heads 110 can be elevated from the test socket board 108, leaving enough space for the transfer of the tray 102 onto the test socket board 108.

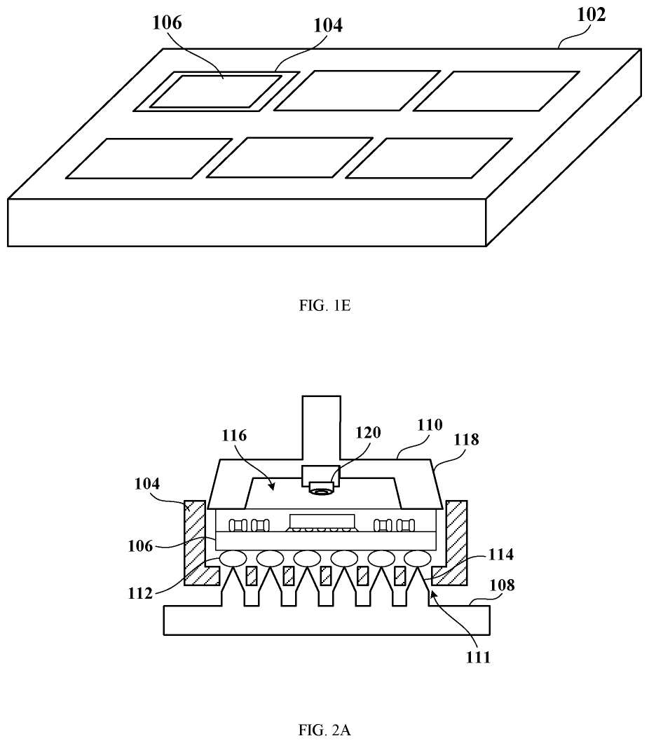

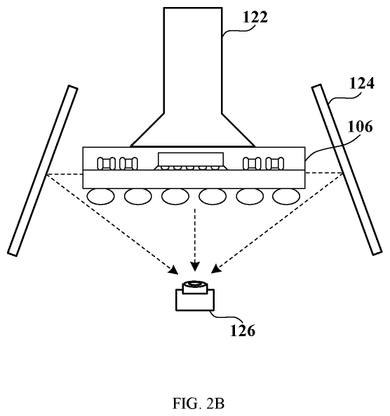

FIG. 2A shows a cross-sectional view of a seat placed on the test socket board at the first testing site shown in FIG. 1B. It can be appreciated that the other seats of the tray may have the same or similar structure.

As shown in FIG. 2A, an electronic package 106 is received within the seat 104. The seat 104 has substantially the same size and shape as the electronic package 106 so that it can be well accommodated within the seat 104 to avoid undesired lateral movement. At the bottom of the seat 106, a set of openings 111 is formed, and each opening 111 is aligned with one of the backside conductive structures 112 of the electronic package 106.

The test socket board 108 is placed under the seat 104, and has a plurality sets of test pins 114 which are electrically coupled to certain test circuit mounted on or coupled to the test socket board 108. Each set of test pins 114 have a layout which is similar to that of the set of backside conductive structures 112 of the electronic package 106 in the seat 104. As the backside conductive structures 112 are exposed from the respective openings 111, the set of test pins 114 can pass through the openings 111 and be connected to the backside conductive structures 112 of the electronic package 106. In this way, the electronic package 106 can be electrically coupled to the test socket board 108 through the backside conductive structures 112 and the test pins 114, to allow the test socket board 108 to perform the electrical test to the electronic package 106.

As aforementioned, a push head 110 is mounted above the seat 104 and displaceable relative to the test socket board 108. In the press position shown in FIG. 2A, the push head 110 is in contact with a top surface of the electronic package 106 to press it downward against the seat 104, to maintain good connection between the backside conductive structures 112 and the test pins 114. When the electrical test is being performed by the test socket board 108 on the electronic package 106, an appearance inspection check can also be performed by the push head 110. In particular, the push head 110 has a cavity 116, which may be generally aligned with a central region of the electronic package 106, and a sidewall 118 surrounding the cavity 116, which is in contact with a peripheral region of the electronic package 106 to apply a compression force to it. A frontside camera 120 can be received in the cavity 116 and face towards the electronic package 106. As such, the frontside camera 120 has a view covering the front surface of the electronic package 106, and can be used to capture a frontside image of the electronic package 106. As a part of the appearance inspection check, the frontside image of the electronic package 106 can be sent to a host device or a server to determine whether there is any appearance defect for the electronic package 106.

In some examples, one or more light sources such as LED devices can be mounted in the cavity 116 to provide auxiliary lighting for the frontside camera 120, especially in cases where the push head 110 is made of non-transparent materials. Furthermore, the light sources and the frontside camera 120 may be mounted on a rail or other similar structures, so that the frontside camera 120 can generate the frontside image by scanning over the electronic package 106. Also, as the peripheral region of the electronic package 106 may be at least partially blocked by the sidewall 118 when the push head 110 is pressing the electronic package 106, in some preferred embodiments, the frontside camera 120 may capture twice, i.e., a first time when the peripheral region is not blocked and a second time when the peripheral region is blocked, to obtain a complete frontside image of the electronic package 106.

It can be appreciated that a cubic object like the electronic package 106 has six surfaces, i.e., a front surface, a back surface and four lateral surfaces. While the frontside camera 120 can capture the frontside image of the electronic package 106, the other five surfaces need to be inspected as well. In order to capture the respective images of these surfaces, a transfer head 122 is provided, as is shown in FIG. 1C, after the push heads are removed. The transfer head 122 can pick up the electronic package 106 from the seat 104 of the tray 102, and transfer the electronic package 106 to a second testing site shown in FIG. 1D.

At the second testing site, the electronic package 106 is held by the transfer head 122 at its front surface and hung in the air. In other words, the four lateral surfaces and the back surface of the electronic package 106 are all exposed and can be inspected. Four mirrors (not shown) are disposed around the electronic package 106, each of which is facing towards one of the four lateral surfaces of the electronic package 106.

FIG. 2B shows a cross-sectional view of an electronic package under appearance inspection at the second testing site shown in FIG. 1D. As shown in FIG. 2B, four mirrors 124 define an inspection space in which the electronic package 106 is hung by the transfer head 122. Each mirror 124 is slightly angled downward towards a backside camera 126 which is right under the electronic package 106. In that case, the images of the lateral surfaces of the electronic package 106 can be captured by the backside camera 126 via the reflection by the mirrors 124. At the same time, as the backside camera 126 is facing towards the back surface of the electronic package 106, it can also capture a backside image of the electronic package 106 directly. As such, the five surfaces which cannot be inspected at the first testing site can be inspected at the second testing site, and thus the entire appearance of the electronic package 106 can be checked. It can be appreciated that the respective angles of the mirrors 124 relative to the electronic package 106 or to the backside camera 126 can be adjusted independently to ensure that the images of the lateral surfaces of the electronic package 106 can be captured. In some embodiments, light sources such as LED device can be disposed, for example, close to the backside camera 126, to irradiate light towards the electronic package 106, either directly or indirectly via the mirrors 124. In this way, the images of the electronic package 106 can be captured with better lighting quality. In some embodiments, the mirrors 124 can be supported by a frame or a rack. Either the frame or rack supporting the mirrors 124 or the transfer head 122 can move, either vertically or horizontally, to improve the alignment between the inspected surfaces of the electronic package 106 and the backside camera 126.

As can be seen from FIGS. 1D and 2B, the five surfaces of the electronic package 106 can be checked at the same time, it is not desired to move the backside camera 126 during the inspection check, and thus, the efficiency of appearance inspection for electronic packages can be improved. It should be noted that although the embodiment shown in FIGS. 1D and 2B illustrates that the backside camera 126 is facing upward, in some alternative embodiments, the direction of the backside camera can be adjusted, for example, facing downward, as long as it can be directed towards the backside surface of the electronic package 106. Also, in some alternative embodiments, two or more transfer heads can be provided for transferring the electronic packages and performing the appearance inspection at the second testing site, to improve a throughput of the testing pipeline at the second testing site.

It can be appreciated that the images of the electronic package 106 captured at the two testing sites, as well as the electrical test results generated at the first testing site, can be sent to the host device or server for further processing. The host device may determine, based on a predetermined quality standard, whether there is any misfunction or disfunction for the electronic package 106 and whether there is any defect in appearance of the electronic package 106. As such, the host device can further determine whether the electronic package 106 is qualified for shipment.

After the electrical test and the appearance inspection at the first and second testing sites is completed, the transfer head 122 can move forward to place the electronic package 106 back into the seat 104 of the tray 102 or to another tray having similar seats, as shown in FIG. 1E. For example, the tray receiving the electronic packages which have been tested and inspected may be placed at another site such as an unloading site. After all the electronic packages 106 have been tested and inspected and have been placed into the tray, the tray can be moved out of the pipeline for subsequent processing such as packing or shipment. It can be appreciated that although in the embodiment shown in FIGS. 1A to 1E, all the six surfaces of an electronic package 106 are inspected, in some alternative embodiments where only the front surface of the electronic package is needed to be inspected, the second testing site and the tools placed there, including the backside camera and the mirrors, can be omitted.

In some embodiments, the electronic packages 106 may be classified into different groups, e.g., a first-grade group without functionality and appearance defects, a second-grade group with appearance defects but no functionality defects, and a third-grade group which are disqualified. The different groups of electronic packages 106 may be placed into different trays and be further processed differently. Also, in the embodiment shown in FIGS. 1A to 1E, the package testing device is in the form of a pipeline, in some other alternative embodiments, the package testing device can take other appropriate forms. For example, the tools such as the push head, the transfer head, the test socket board and the frontside and backside cameras can be integrated together as a machine or platform which can implement the steps of the testing method described above, with some of the transfer step(s) omitted.

The discussion herein included numerous illustrative figures that showed various portions of a package testing device, pipeline and method. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A package testing device, comprising:
a tray having a seat for receiving an electronic package with a set of backside conductive structures, and a set of openings formed at and passing through a bottom of the seat; wherein the set of openings are configured to expose the set of backside conductive structures when the electronic package is received in the seat;
a push head displaceable relative to the tray and configured to press the electronic package against the seat when the electronic package is received within the seat; wherein the push head has a cavity, and a frontside camera received in the cavity and configured to capture a frontside image of the electronic package; and
a test socket board for performing an electrical test to the electronic package, wherein the test socket board has a set of test pins which are operable to pass through the set of openings of the seat and be connected to the set of backside conductive structures of the electronic package to allow the test socket board to perform the electrical test to the electronic package.

2. The package testing device of claim 1, wherein the frontside camera is further configured to capture the frontside image of the electronic package when the push head is pressing the electronic package against the seat.

3. The package testing device of claim 1, further comprising:
a transfer head displaceable relative to the tray and configured to pick up the electronic package from the seat and transfer the electronic package to an inspection space;
a backside camera disposed under the inspection space; and
an array of mirrors surrounding the inspection space and configured to reflect images of respective lateral surfaces of the electronic package in the inspection space to the backside camera to allow the backside camera to capture the images of the lateral surfaces of the electronic package and a backside image of the electronic package.

4. The package testing device of claim 3, wherein the array of mirrors comprises four mirrors disposed at four lateral sides of the electronic package, respectively, when the electronic package is in the inspection space.

5. A package testing pipeline, comprising:
a tray loading site for placing a tray having a plurality of seats; wherein each of the plurality of seats is configured for receiving an electronic package with a set of backside conductive structures, and a set of openings formed at and passing through a bottom of the seat, and wherein the set of openings are configured to expose the set of backside conductive structures when the electronic package is received in the seat;
a first testing site for placing a test socket board for performing an electrical test to the electronic packages received within the seats of the tray when the tray is transferred from the tray loading site onto the test socket board, and for placing a plurality of push heads displaceable relative to the test socket board and configured to press the electronic packages against the plurality of seats of the tray when the tray is on the test socket board; wherein each of the push heads has a cavity, and a frontside camera received in the cavity and configured to capture a frontside image of the electronic package; and wherein the test socket board has a plurality sets of test pins, and each set of test pins are operable to pass through the set of openings of a seat of the plurality of seats of the tray and be connected to the set of backside conductive structures of the electronic package within the seat to allow the test socket board to perform the electrical test to the electronic package;
a second testing site having a backside camera, and an array of mirrors disposed above the backside camera and defining an inspection space and configured to reflect images of respective lateral surfaces of the electronic package in the inspection space to the backside camera to allow the backside camera to capture the images of the lateral surfaces of the electronic package and a backside image of the electronic package; and
a transfer head configured to pick up the electronic package from one of the plurality of seats of the tray and transfer the electronic package to the second testing site.

6. The package testing pipeline of claim 5, wherein the frontside camera is further configured to capture the frontside image of the electronic package when the push head is pressing the electronic package against the seat.

7. The package testing pipeline of claim 5, wherein the array of mirrors comprises four mirrors disposed at four lateral sides of the electronic package, respectively, when the electronic package is in the inspection space.

8. The package testing pipeline of claim 5, further comprising an unloading site, wherein the transfer head is further configured to transfer the electronic package from the second testing site to the unloading site.

9. (canceled)

10. (canceled)

11. (canceled)

12. (canceled)

13. A package testing method, comprising:
placing a tray having a plurality of seats at a tray loading site, wherein each set of the plurality of seats has a set of openings formed at and passing through a bottom of the seat;
loading an electronic package with a set of backside conductive structures within each of the plurality of seats to expose the set of backside conductive structures through the set of openings at the bottom of the seat;
transferring the tray with the plurality of electronic packages from the tray loading site onto a test socket board having a plurality sets of test pins at a first testing site;
pressing, via a plurality of push heads each having a cavity and a frontside camera received in the cavity, the electronic packages against the plurality of seats, respectively, to pass the plurality sets of test pins through the plurality sets of openings of the plurality of seats and connect the plurality sets of test pins to the plurality sets of backside conductive structures of the electronic packages;
capturing, via the frontside cameras of the plurality of push heads, respective frontside images of the electronic packages; and
performing, via the test socket board, an electrical test to the electronic packages.

14. The package testing method of claim 13, further comprising:
displacing the push heads away from the test socket board;
picking up, via a transfer head, one of the electronic packages from one of the plurality of seats of the tray;
transferring, via the transfer head, the electronic package to an inspection space having an array of mirrors surrounding the inspection space which are configured to reflect images of respective lateral surfaces of the electronic package in the inspection space to a backside camera under the inspection space; and
capturing, via the backside camera, the images of the lateral surfaces of the electronic package and a backside image of the electronic package.

15. The package testing method of claim 14, further comprising:
placing, via the transfer head, the electronic package back into one of the plurality of seats of the tray.

16. The package testing method of claim 15, further comprising:
transferring, via the transfer head, the tray with the electronic packages to an unloading site.

17. The package testing method of claim 14, wherein the array of mirrors comprises four mirrors disposed at four lateral sides of the electronic package, respectively, when the electronic package is in the inspection space.
